(19) United States
(12) Patent Application Publication
(10) Pub. No.: US 2026/0033308 A1
(43) Pub. Date: Jan. 29, 2026

(54) SEMICONDUCTOR STRUCTURE AND MANUFACTURING METHOD THEREOF

(71) Applicant: NANYA TECHNOLOGY CORPORATION, New Taipei City (TW)

(72) Inventors: Shing-Yih SHIH, New Taipei City (TW); Tse-Yao HUANG, New Taipei City (TW)

(21) Appl. No.: 18/788,097

(22) Filed: Jul. 29, 2024

(51) Int. Cl. H01L 23/00; H01L 23/48; H01L 25/18; H10B 80/00

(52) U.S. Cl. CPC H01L 24/05; H01L 23/481; H01L 24/03; H01L 24/08; H01L 24/06; H01L 25/18; H01L 2224/03614; H01L 2224/03616; H01L 2224/05005; H01L 2224/05017; H01L 2224/05147; H01L 2224/05166; H01L 2224/05181; H01L 2224/05187; H01L 2224/05541; H01L 2224/05647; H01L 2224/05666; H01L 2224/05681; H01L 2224/05687; H01L 2224/0603; H01L 2224/06051; H01L 2224/08147; H01L 2924/1431; H01L 2924/1436; H10B 80/00

(57) ABSTRACT

The present disclosure provides a semiconductor structure and a manufacturing method thereof. A semiconductor structure includes a first chip. The first chip includes a first interconnect layer, a first conductive layer disposed on the first interconnect layer, a first dielectric layer covering the first conductive layer, and a first bonding pad embedded in the first dielectric layer and extending into the first conductive layer. The method of manufacturing the semiconductor structure includes the following operations. A first conductive layer is formed on a first interconnect layer. A first dielectric layer is formed on the first conductive layer and the first interconnect layer. The first dielectric layer is etched to form a first trench on the first conductive layer. A portion of the first conductive layer is etched to form a second trench. A first bonding pad is formed in the second trench.

### BACKGROUND

### Field of Invention

The present disclosure relates to a semiconductor structure and a manufacturing method of the semiconductor structure.

### Description of Related Art

To pursue smaller dimension of the semiconductor components and smaller occupied area of the semiconductor structures, chip-on-chip and chip-on-wafer techniques are widely used in the manufacture of the semiconductor package structures.

Chip-on-chip stacks and chip-on-wafer stacks not only decrease the occupied area of the semiconductor package structures, but also increase the memory capacity and integrated density. Increasing the memory capacity and integrated density cause faster speeds and greater bandwidths. However, several challenges still exist in chip-on-chip stacks and chip-on-wafer stacks.

### SUMMARY

The present disclosure provides a semiconductor structure. The semiconductor structure includes a first chip. The first chip includes a first interconnect layer, a first conductive layer disposed on the first interconnect layer, a first dielectric layer covering the first conductive layer, and a first bonding pad embedded in the first dielectric layer and extending into the first conductive layer.

In some embodiments, the first chip further includes an anti-reflection layer disposed between the first conductive layer and the first dielectric layer and on the first conductive layer.

In some embodiments, the first bonding pad includes a first metal layer and a second metal layer, and the first metal layer surrounds the second metal layer.

In some embodiments, a cross-section of the first bonding pad includes a top width, a bottom width, and a middle width that is less than or the same as the top width and the bottom width.

In some embodiments, the top width is greater than the bottom width.

In some embodiments, the semiconductor structure further includes a second chip disposed on the first chip, in which the second chip includes a second dielectric layer, a substrate disposed on the second dielectric layer, a second bonding pad embedded in the second dielectric layer and bonded to the first bonding pad, and a through silicon via embedded in the second dielectric layer and the substrate and in contact with the second bonding pad.

In some embodiments, a bonding interface between the first bonding pad and the second bonding pad is substantially flat.

In some embodiments, the second bonding pad includes a first metal layer and a second metal layer, and the first metal layer surrounds the second metal layer.

In some embodiments, a cross-section of the second bonding pad includes a top width and a bottom width that is greater or the same as the top width.

The present disclosure provides a method of manufacturing a semiconductor structure. The method includes the following operations. A first conductive layer is formed on a first interconnect layer. A first dielectric layer is formed on the first conductive layer and the first interconnect layer. The first dielectric layer is etched to form a first trench on the first conductive layer. A portion of the first conductive layer is etched to form a second trench. A first bonding pad is formed in the second trench.

In some embodiments, the method further includes the following operations. Before the first dielectric layer is formed on the first conductive layer and the first interconnect layer, an anti-reflection layer is formed on the first conductive layer. Before the portion of the first conductive layer is etched to form the second trench, a portion of the anti-reflection layer is etched.

In some embodiments, forming the first bonding pad in the second trench includes sequentially depositing a first metal layer and a second metal layer in the second trench.

In some embodiments, a grain size of the first metal layer is greater than a grain size of the second metal layer.

In some embodiments, the method further includes the following operations. A first substrate and a through silicon via embedded in the first substrate are received. The first substrate is etched to expose the through silicon via. A second dielectric layer is formed to cover the first substrate and the through silicon via. The second dielectric layer is etched to form a third trench and to expose the through silicon via. A second bonding pad is formed in the third trench. The first bonding pad is bonded to the second bonding pad.

In some embodiments, forming the second bonding pad in the third trench includes sequentially forming a first metal layer and a second metal layer in the third trench.

In some embodiments, a grain size of the first metal layer is greater than a grain size of the second metal layer.

It is to be understood that both the foregoing general description and the following detailed description are by examples, and are intended to provide further explanation of the invention as claimed.

### BRIEF DESCRIPTION OF THE DRAWINGS

The present disclosure can be more fully understood by reading the following detailed description of the embodiment, with reference made to the accompanying drawings.

FIG. 1A is a cross-sectional view of semiconductor structure, in accordance with some embodiments.

FIG. 1B is an enlarged diagram of the section A in FIG. 1A.

FIG. 1C is a cross-sectional view of semiconductor structure, in accordance with some embodiments.

FIG. 1D is an enlarged diagram of the section B in FIG. 1C.

FIGS. 2A-2B are flow diagrams of a method of manufacturing semiconductor structures, in accordance with some embodiments.

FIGS. 3, 5, 6, 7, 9, 10A, and 11A are cross-sectional views illustrating intermediate stages of manufacturing a semiconductor structure according to various embodiments of the present disclosure.

FIG. 4A is an enlarged diagram of the section C in FIG. 3.

FIGS. 4B-4F illustrate intermediate stages of manufacturing a semiconductor structure that continues from FIG. 4A.

FIG. 8A is an enlarged diagram of the section D in FIG. 7.

FIGS. 8B-8G illustrate intermediate stages of manufacturing a semiconductor structure that continues from FIG. 8A.

FIG. 10B is an enlarged diagram of the section E in FIG. 10A.

FIG. 11B is an enlarged diagram of the section F in FIG. 11A.

FIGS. 12A-13 are cross-sectional views illustrating intermediate stages of manufacturing a semiconductor package structure according to various embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

It is appreciated that although the terms “first”, “second”, “third”, etc., may be used in this document to describe different components, parts, regions, layers and/or parts, such components, parts, regions, layers and/or parts shall not be limited by these terms. These terms are used only to distinguish an assembly, part, region, layer, or part from another component, part, region, layer, or part. Therefore, the “first element”, “component”, “region”, “layer” or “section” discussed below may be referred to as a second element, component, region, layer or part without departing from the teachings herein.

The present disclosure relates to structures which are made up of different layers. When the terms “on” or “upon” or “over” are used with reference to two different layers (including the substrate), they indicate merely that one layer is on or upon the other layer. These terms do not require the two layers to directly contact each other, and permit other layers to be between the two layers. For example, all layers of the structure can be considered to be “on” the substrate, even though they do not all directly contact the substrate.

The present disclosure provides a semiconductor structure and a manufacturing method of the semiconductor structure. In the semiconductor structure, a bonding pad extends into a conductive layer, which increases the contact area between the conductive layer and the bonding pad, such that the resistance of the conductive layer and the bonding pad become smaller.

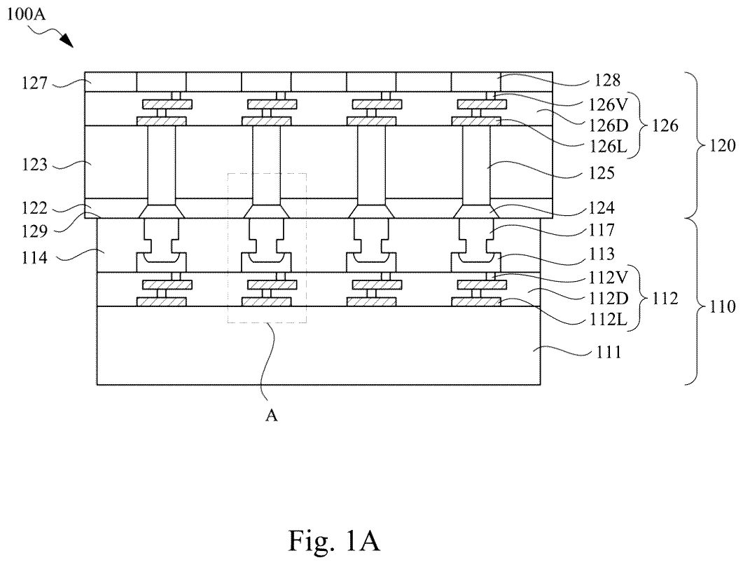

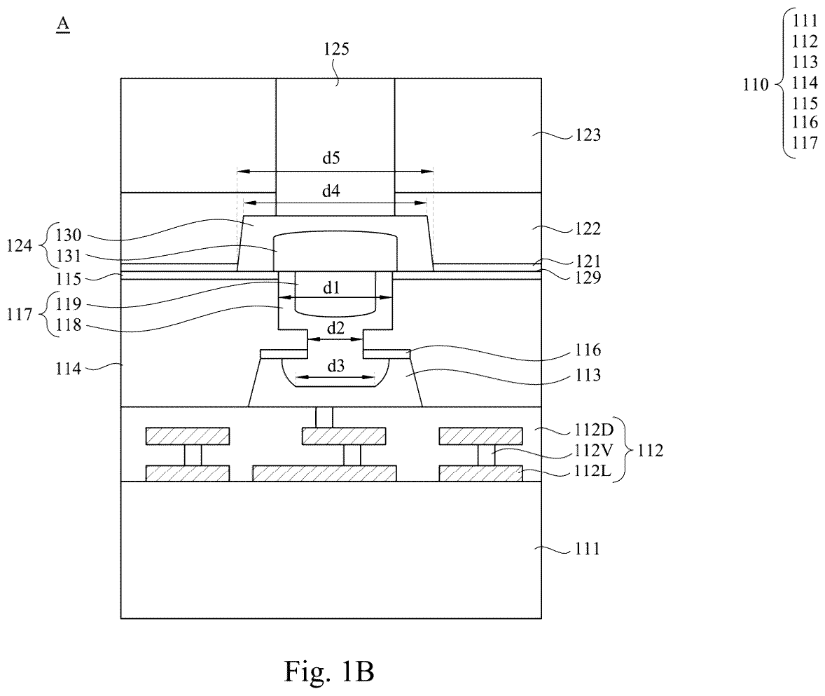

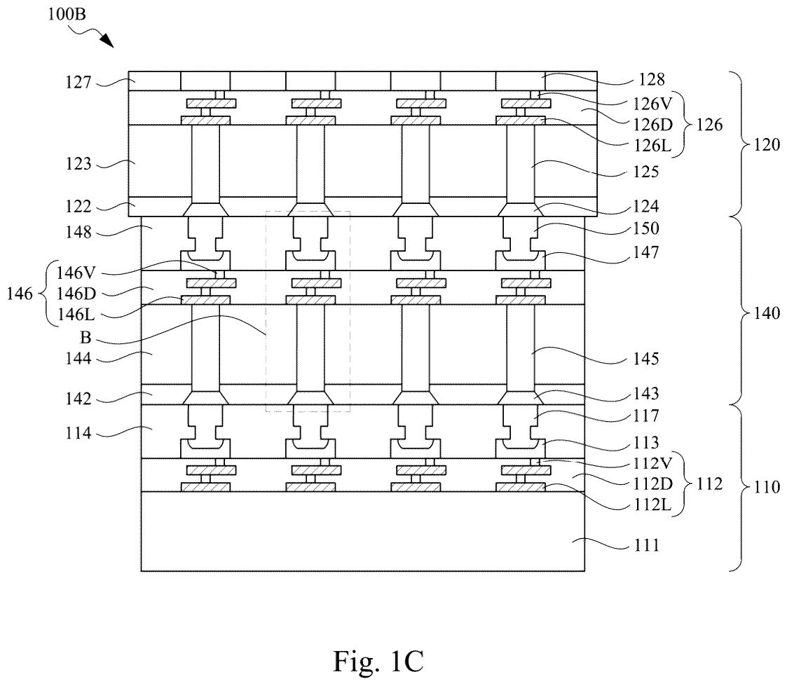

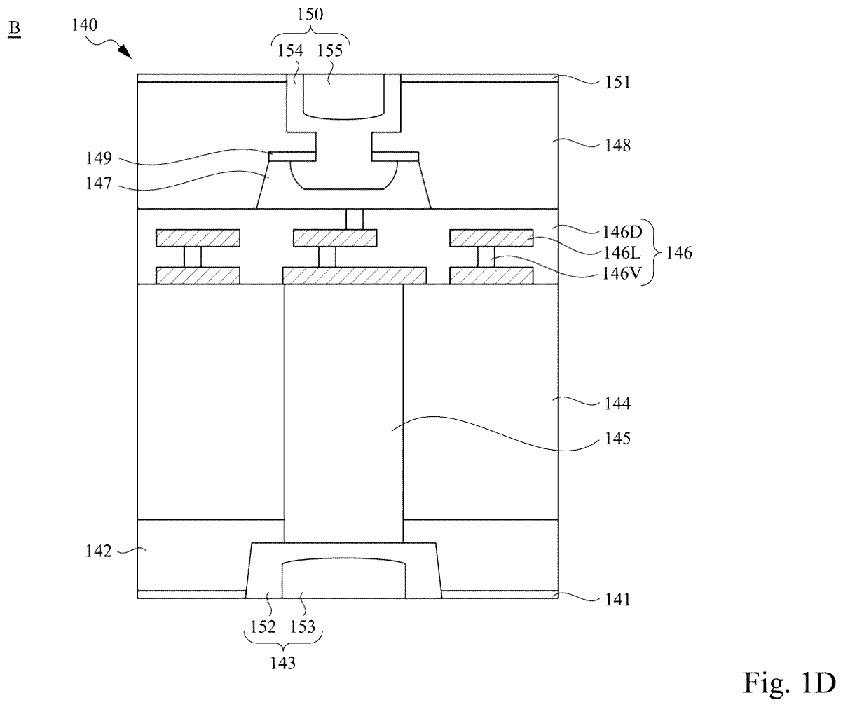

FIG. 1A is a cross-sectional view of semiconductor structure 100A, in accordance with some embodiments. FIG. 1B is an enlarged diagram of the section A in FIG. 1A. To simplify the diagram in FIG. 1A, portions of the semiconductor components are merely shown in FIG. 1B, but not shown in FIG. 1A. Refer to both FIGS. 1A-1B, the semiconductor structure 100A includes a first chip 110. The first chip 110 includes a substrate 111, a first interconnect layer 112, a first conductive layer 113, a first dielectric layer 114, an inorganic barrier layer 115, an anti-reflection layer 116, and a first bonding pad 117. In some embodiments, the substrate 111 includes a silicon (Si) substrate, a substrate formed of a material including Si, a Si on insulator (SOI) substrate, or other types of semiconductor material.

As shown in FIGS. 1A-1B, the first interconnect layer 112 is disposed on the substrate 111. The first interconnect layer 112 includes a plurality of conductive lines 112L, a plurality of conductive vias 112V, and a dielectric layer 112D. The conductive lines 112L and the conductive vias 112V are disposed in the dielectric layer 112D. The conductive lines 112L and the conductive vias 112V are embedded in the dielectric layer 112D, in which the conductive lines 112L are interconnected with the conductive vias 112V. In some embodiments, the conductive lines 112L and the conductive vias 112V respectively include conductive materials such as aluminum (AI), copper (Cu), titanium (Ti), ruthenium (Ru), or tungsten (W), but the present disclosure is not limited thereto. In some embodiments, the dielectric layer 112D include, for example and without limitation, silicon dioxide (SiO₂), boron-containing silicate glass (BSG), fluorine-containing silicate glass (FSG), silicon nitride (Si₃N₄), silicon carbide (SiC), borophosphosilicate glass (BPSG), silicon oxynitride (SiON), or combinations thereof. In some embodiments, a diffusion barrier layer (not shown) is disposed between the conductive lines 112L/the conductive vias 112V and the dielectric layer 112D. In some embodiments, the diffusion barrier layer includes, for example and without limitation, titanium nitride (TiN) or tantalum nitride (TaN). The first interconnect layer 112 may electrically connected to other components in the first chip 110, and it will be described below.

As shown in FIGS. 1A-1B, the first conductive layer 113 is disposed on the first interconnect layer 112. In some embodiments, the first conductive layer 113 includes metal such as Al, W, Cu, Ti, or Ru, but the present disclosure is not limited thereto. In some embodiments, a top surface of the first conductive layer 113 is concave, but the concave shape is not limited to FIG. 1B. The first conductive layer 113 may be electrically connected to the first interconnect layer 112. The semiconductor structure 100A may be implemented with any numbers of the first conductive layer 113, e.g., one, two, three, four, five, etc.

As shown in FIGS. 1A-1B, the first dielectric layer 114 covers the first conductive layer 113. In some embodiments, the first dielectric layer 114 includes, for example and without limitation, SiO₂, BSG, FSG, Si₃N₄, SiC, BPSG, SiON, or combinations thereof. As shown in FIGS. 1A-1B, the inorganic barrier layer 115 is disposed on the first dielectric layer 114. In some embodiments, the inorganic barrier layer 115 includes, for example and without limitation, SiO₂, silicon carbon nitride (SiCN), SiN, SiON, SiC, or combinations thereof.

As shown in FIGS. 1A-1B, the anti-reflection layer 116 is disposed between the first conductive layer 113 and the first dielectric layer 114 and on the first conductive layer 113. In some embodiments, the anti-reflection layer 116 includes TiN, Ti, or a combination thereof, but the present disclosure is not limited thereto. The anti-reflection layer 116 may prevent the first conductive layer 113 from being etched into unintended patterns after subsequent light exposure and development.

As shown in FIGS. 1A-1B, the first bonding pad 117 is embedded in the first dielectric layer 114 and the inorganic barrier layer 115, and extends into the first conductive layer 113. In some embodiments, a top surface of the first bonding pad 117 is substantially coplanar with a top surface of the inorganic barrier layer 115. In some embodiments, the first bonding pad 117 includes a first metal layer 118 and a second metal layer 119, and the first metal layer 118 surrounds the second metal layer 119. In some embodiments, the first metal layer 118 extends into the first conductive layer 113. In some embodiments, the first metal layer 118 and the second metal layer 119 respectively include TaN, Ta, TiN, Ti, Cu, or combinations thereof. In some embodiments, the first metal layer 118 and the second metal layer 119 include the same materials. In some embodiments, the first metal layer 118 and the second metal layer 119 include different materials. In some embodiments, the first bonding pad 117 is a pillar structure. In some embodiments, a cross-section of the first bonding pad 117 includes a top width d1, a bottom width d3, and a middle width d2 that is less than or the same as the top width d1 and the bottom width d3. In some embodiments, the top width d1 is greater than the bottom width d3. The first bonding pad 117 provides a larger surface for electrical connection to other components. The first bonding pad 117 extends into the first conductive layer 113 can increase the contact area between the first conductive layer 113 and the first bonding pad 117, such that a resistance of the first conductive layer 113 and the first bonding pad 117 become smaller, compared to the semiconductor structure that the bonding pad does not extend into the conductive layer. The semiconductor structure 100A may be implemented with any numbers of the first bonding pad 117, e.g., one, two, three, four, five, etc.

As shown in FIGS. 1A-1B, the semiconductor structure 100A further includes a second chip 120 disposed on the first chip 110, in which the second chip 120 includes an inorganic barrier layer 121, a second dielectric layer 122, a first substrate 123, a second bonding pad 124, a through silicon via 125, a second interconnect layer 126, a third dielectric layer 127, and a second conductive layer 128. In some embodiments, the inorganic barrier layer 121 includes, for example and without limitation, SiO₂, SiCN, SIN, SiON, or SiC. In some embodiments, the inorganic barrier layer 121 is bonded to the inorganic barrier layer 115. In some embodiments, a bonding interface 129 between the inorganic barrier layer 121 and the inorganic barrier layer 115 is substantially flat. As shown in FIGS. 1A-1B, the second dielectric layer 122 is disposed on the inorganic barrier layer 121. In some embodiments, the second dielectric layer 122 includes, for example and without limitation, SiO₂, BSG, FSG, Si₃N₄, SiC, BPSG, SiON, or combinations thereof. As shown in FIGS. 1A-1B, the first substrate 123 is disposed on the second dielectric layer 122. In some embodiments, the first substrate 123 includes a Si substrate, a substrate formed of a material including Si, a SOI substrate, or other types of semiconductor material.

As shown in FIGS. 1A-1B, the second bonding pad 124 is embedded in the second dielectric layer 122 and the inorganic barrier layer 121, and bonded to the first bonding pad 117. In some embodiments, a bottom surface of the second bonding pad 124 is substantially coplanar with a bottom of the inorganic barrier layer 121. In some embodiments, the bonding interface 129 between the first bonding pad 117 and the second bonding pad 124 is substantially flat. In some embodiments, the second bonding pad 124 includes a first metal layer 130 and a second metal layer 131, and the first metal layer 130 surrounds the second metal layer 131. In some embodiments, the first metal layer 130 and the second metal layer 131 respectively include TaN, Ta, TiN, Ti, Cu, or combinations thereof. In some embodiments, the first metal layer 130 and the second metal layer 131 include the same materials. In some embodiments, the first metal layer 130 and the second metal layer 131 include different materials. In some embodiments, the second bonding pad 124 is a pillar structure. In some embodiments, a cross-section of the second bonding pad 124 includes a top width d4 and a bottom width d5 that is greater or the same as the top width d4. The second bonding pad 124 provides a larger surface for electrical connection to other components. The semiconductor structure 100A may be implemented with any numbers of the second bonding pad 124, e.g., one, two, three, four, five, etc.

As shown in FIGS. 1A-1B, a through silicon via 125 is embedded in the second dielectric layer 122 and the first substrate 123 and in contact with the second bonding pad 124. In some embodiments, a top surface of the through silicon via 125 is substantially coplanar with a top surface of the first substrate 123. The semiconductor structure 100A may be implemented with any numbers of the through silicon via 125, e.g., one, two, three, four, five, etc. As shown in FIGS. 1A-1B, the second interconnect layer 126 is disposed on the first substrate 123 and the through silicon via 125. The second interconnect layer 126 includes a plurality of conductive lines 126L, a plurality of conductive vias 126V, and a dielectric layer 126D. The conductive lines 126L and the conductive vias 126V are disposed in the dielectric layer 126D. The conductive lines 126L and the conductive vias 126V are embedded in the dielectric layer 126D, in which the conductive lines 126L are interconnected with the conductive vias 126V. Please refer to the aforementioned embodiments of the conductive lines 112L, the conductive vias 112V, and the dielectric layer 112D for the embodiments of the conductive lines 126L, the conductive vias 126V, and the dielectric layer 126D. The second interconnect layer 126 may be electrically connected to the through silicon via 125 and other components in the second chip 120, which will be described below.

As shown in FIG. 1A, the third dielectric layer 127 is disposed on the second interconnect layer 126. In some embodiments, the third dielectric layer 127 includes, for example and without limitation, SiO₂, BSG, FSG, Si₃N₄, SiC, BPSG, SiON, or combinations thereof. As shown in FIG. 1A, the second conductive layer 128 is embedded in the third dielectric layer 127. In some embodiments, a top surface of the second conductive layer 128 is substantially coplanar with a top surface of the third dielectric layer 127. In some embodiments, the second conductive layer 128 includes metal such as Al, W, Cu, Ti, or Ru, but the present disclosure is not limited thereto. In some embodiments, a cross-section of the second conductive layer 128 is rectangle or trapezoid, but the present disclosure is not limited thereto. The second conductive layer 128 may be electrically connected to the second interconnect layer 126. The semiconductor structure 100A may be implemented with any numbers of the second conductive layer 128, e.g., one, two, three, four, five, etc.

FIG. 1C is a cross-sectional view of the semiconductor structure 100B, in accordance with some embodiments. FIG. 1D is an enlarged diagram of the section B in FIG. 1C. To simplify the diagram in FIG. 1C, portions of the semiconductor components are merely shown in FIG. 1D, but not shown in FIG. 1C. Refer to both FIGS. 1C-1D, the semiconductor structure 100B further includes a first chip 140 disposed between the first chip 110 and the second chip 120. The first chip 140 includes an inorganic barrier layer 141, a second dielectric layer 142, a second bonding pad 143, a substrate 144, a through silicon via 145, a first interconnect layer 146, a first conductive layer 147, a first dielectric layer 148, an anti-reflection layer 149, a first bonding pad 150, an inorganic barrier layer 151. The inorganic barrier layer 141 is bonded to the inorganic barrier layer 115 (not shown). Please refer to the aforementioned embodiments of the inorganic barrier layer 121 for the embodiments of the inorganic barrier layer 141. As shown in FIGS. 1C-1D, the second dielectric layer 142 is disposed on the inorganic barrier layer 141. Please refer to the aforementioned embodiments of the second dielectric layer 122 for the embodiments of the second dielectric layer 142. The second bonding pad 143 is embedded in the second dielectric layer 142 and the inorganic barrier layer 141, and bonded to the first bonding pad 117. In some embodiments, the second bonding pad 143 includes a first metal layer 152 and a second metal layer 153, and the first metal layer 152 surrounds the second metal layer 153. Please refer to the aforementioned embodiments of the second bonding pad 124, the first metal layer 130, and the second metal layer 131 for the embodiments of the second bonding pad 143, the first metal layer 152, and the second metal layer 153. The substrate 144 is disposed on the second dielectric layer 142. Please refer to the aforementioned embodiments of the first substrate 123 for the embodiments of the substrate 144. The through silicon via 145 is embedded in the substrate 144 and the second dielectric layer 142 and in contact with the second bonding pad 143. Please refer to the aforementioned embodiments of the through silicon via 125 for the embodiments of the through silicon via 145. The first interconnect layer 146 is disposed on the substrate 144 and the through silicon via 145. The first interconnect layer 146 includes a plurality of conductive lines 146L, a plurality of conductive vias 146V, and a dielectric layer 146D. Please refer to the aforementioned embodiments of the first interconnect layer 112, the conductive lines 112L, the conductive vias 112V, and the dielectric layer 112D for the embodiments of the first interconnect layer 146, the conductive lines 146L, the conductive vias 146V, and the dielectric layer 146D. Please refer to the aforementioned embodiments of the first conductive layer 113, the first dielectric layer 114, the anti-reflection layer 116, the first bonding pad 117, and the inorganic barrier layer 115 for the embodiments of the first conductive layer 147, the first dielectric layer 148, the anti-reflection layer 149, the first bonding pad 150, and the inorganic barrier layer 151. The first bonding pad 150 and the inorganic barrier layer 151 are respectively bonded to the second bonding pad 124 and the inorganic barrier layer 121 (not shown). In some embodiments, the first bonding pad 150 includes a first metal layer 154 and a second metal layer 155, and the first metal layer 154 surrounds the second metal layer 155. Please refer to the aforementioned embodiments of the first metal layer 118 and the second metal layer 119 for the embodiments of the first metal layer 154 and the second metal layer 155.

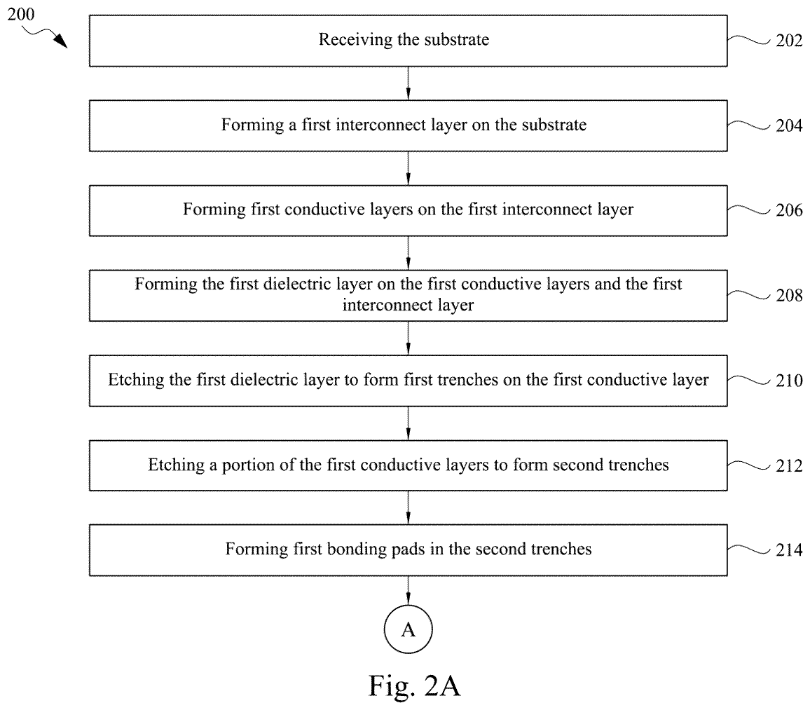

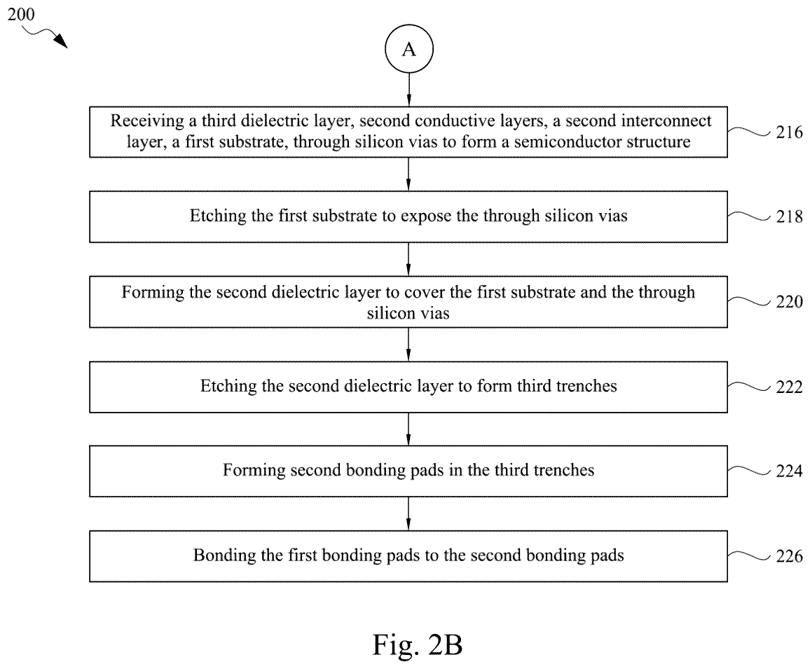

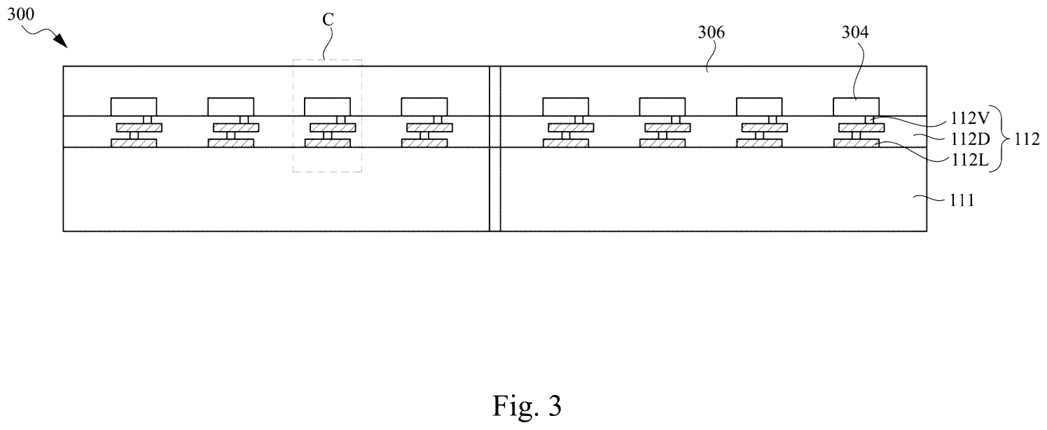

FIGS. 2A-2B are flow diagrams of a method 200 of manufacturing the semiconductor structures 100A, in accordance with some embodiments. The method 200 includes operation 202, operation 204, operation 206, operation 208, operation 210, operation 212, operation 214, operation 216, operation 218, operation 220, operation 222, operation 224, and operation 226. FIGS. 3, 5, 6, 7, 9, 10A, 11A are cross-sectional views illustrating intermediate stages of manufacturing the semiconductor structures 100A according to various embodiments of the present disclosure. Although a series of operations are used below to describe the method disclosed herein, an order of these operations or steps should not be construed as a limitation to the present disclosure. For example, some operations may be performed in a different order, and/or other steps may be performed at the same time. In addition, it is not necessary to perform all of the operations and/or features shown to achieve the embodiments of the present disclosure. In addition, each operations described herein may contain several sub-steps or actions. It is noted that the numbers of the semiconductor components in FIGS. 3-11B are not limited thereto, in other words, the numbers of the semiconductor components can be one, two, three, four, five, etc.

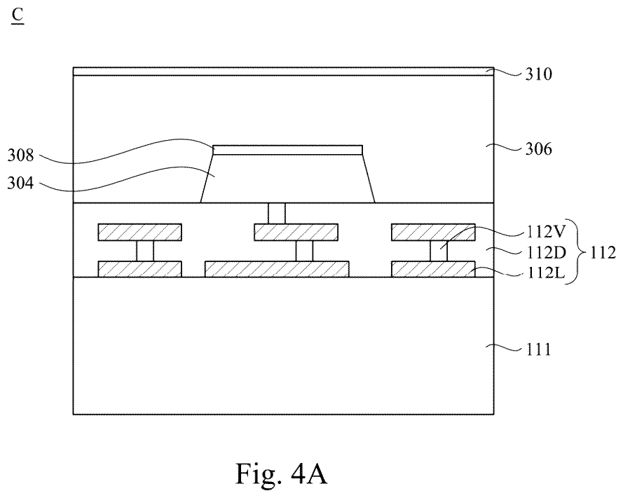

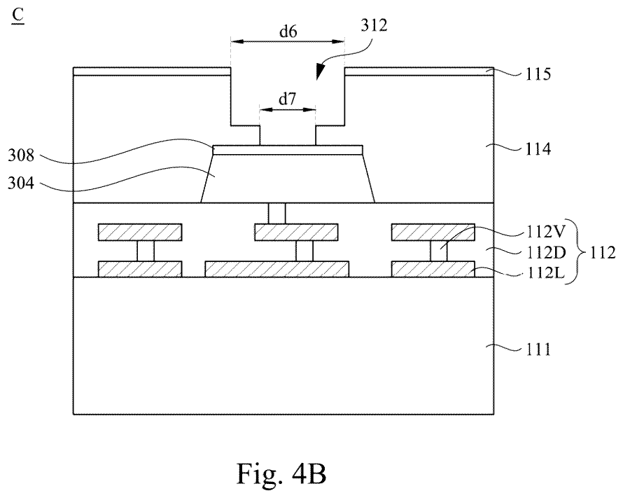

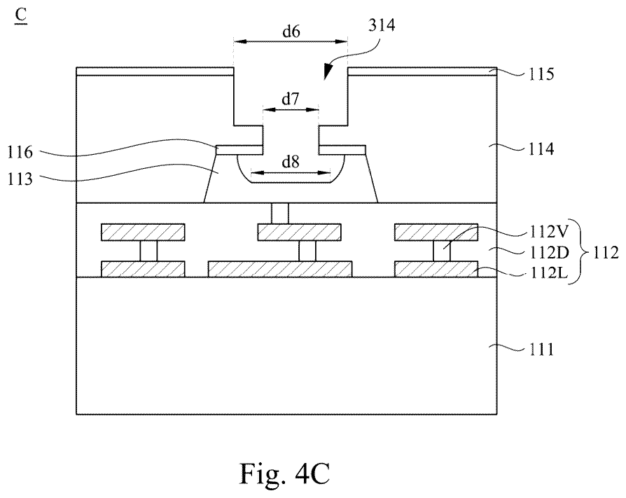

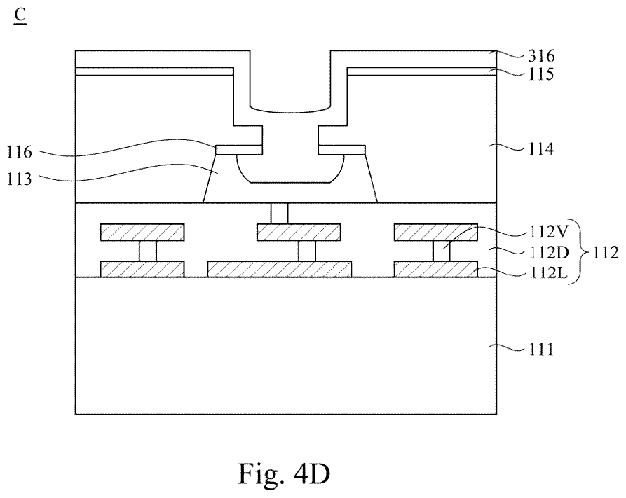

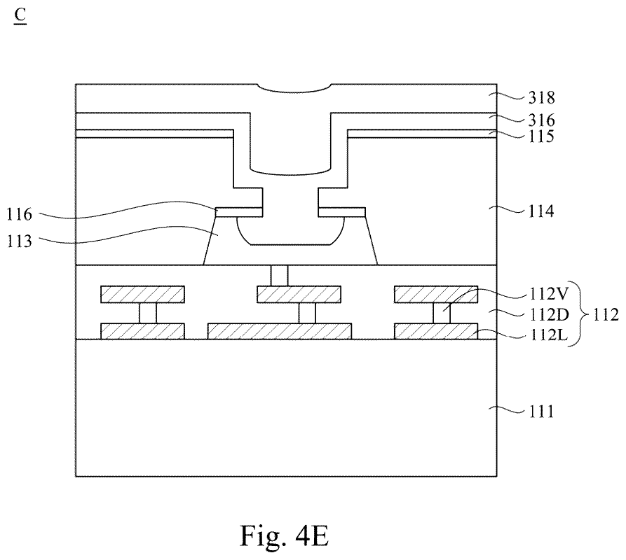

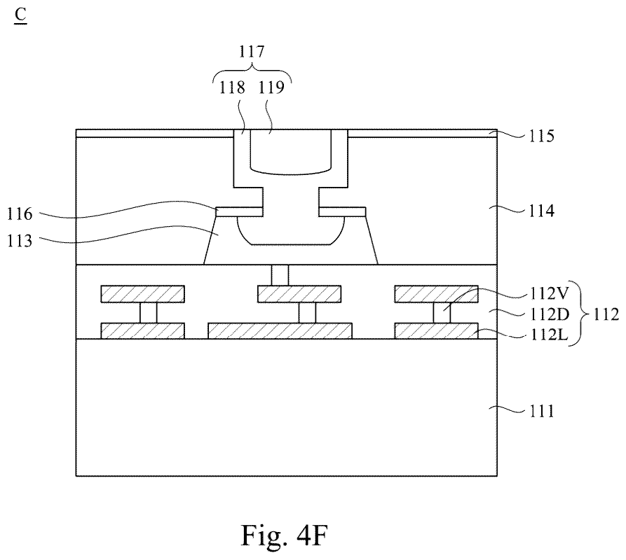

FIG. 3 is a cross-sectional view of a semiconductor structure 300. FIG. 4A is an enlarged diagram of the section C in FIG. 3. To simplify the diagram in FIG. 3, portions of the semiconductor components are merely shown in FIG. 4A, but not shown in FIG. 3. Refer to FIGS. 2A, 3, and 4A, the method 200 begins with operation 202, the substrate 111 is received. In operation 204, the first interconnect layer 112 is formed on the substrate 111. The first interconnect layer 112 may be formed by the following operations. A plurality of conductive lines 112L and a plurality of conductive vias 112V are formed, followed by the deposition of the dielectric layer 112D to cover the conductive lines 112L and the conductive vias 112V. In some embodiments, the conductive lines 112L, the conductive vias 112V, and the dielectric layer 112D are formed by chemical vapor deposition (CVD), physical vapor deposition (PVD), atomic layer deposition (ALD), low pressure CVD (LPCVD), another deposition process, or any suitable combination thereof. In operation 206, one or more first conductive layers 304 are formed on the first interconnect layer 112. In some embodiments, the first conductive layers 304 are formed by the deposition process such as CVD, PVD, ALD, LPCVD, another deposition process, or any suitable combination thereof. In operation 208, the first dielectric layer 306 is formed on the first conductive layers 304 and the first interconnect layer 112. In some embodiments, the first dielectric layer 306 is formed by the deposition process such as CVD, PVD, ALD, LPCVD, another deposition process, or any suitable combination thereof. Before the first dielectric layer 306 is formed on the first conductive layers 304 and the first interconnect layer 112, one or more anti-reflection layers 308 are formed on the first conductive layers 304. In some embodiments, the anti-reflection layers 308 are formed by the deposition process such as CVD, PVD, ALD, LPCVD, another deposition process, or any suitable combination thereof. After operation 208, the inorganic barrier layer 310 is deposited on the first dielectric layer 306 to form the semiconductor structure 300. In some embodiments, the inorganic barrier layer 310 is formed by the deposition process such as CVD, PVD, ALD, LPCVD, another deposition process, or any suitable combination thereof.

Referring to FIGS. 2A, 4A, and 4B, in operation 210, the first dielectric layer 306 is etched to form one or more first trenches 312 and the first dielectric layer 114 on the first conductive layers 304. Before the first dielectric layer 306 is etched, the inorganic barrier layer 310 is etched to form the inorganic barrier layer 115. In some embodiments, the first dielectric layer 306 and the inorganic barrier layer 310 are etched by a dry etching process. In some embodiments, the first trenches 312 include a top width d6 and a neck width d7. In some embodiments, the top width d6 is greater than or same as the neck width d7.

Referring to FIGS. 2A, 4B, and 4C, in operation 212, a portion of the first conductive layers 304 are etched to form one or more second trenches 314 and the first conductive layers 113. Before a portion of the first conductive layers 304 are etched to form the second trenches 314, a portion of the anti-reflection layers 308 are etched to form the anti-reflection layers 116. In some embodiments, the first conductive layers 304 and the anti-reflection layers 308 are etched by a dry etching process. In some embodiments, the second trenches 314 are pillar structures. In some embodiments, the second trenches 314 include the top width d6, the neck width d7, and a bottom width d8, in which the neck width d7 is less than or the same as the top width d6 and the bottom width d8. In some embodiments, the top width d6 is greater than the bottom width d8. A portion of the first conductive layers 304 etched to form the second trenches 314 can increase the contact area between the first conductive layers 113 and the components depositing in the second trenches 314, such that the resistance of the first conductive layers 113 and the components depositing in the second trenches 314 become smaller, compared to the semiconductor structure that the components depositing in the trenches does not extend into the conductive layers.

Referring to FIGS. 2A and 4C-4F, in operation 214, one or more first bonding pads 117 are formed in the second trenches 314. In some embodiments, the first bonding pads 117 formed in the second trenches 314 include a first metal layer 316 and a second metal layer 318 deposited sequentially in the second trenches 314. In detail, the first metal layer 316 is substantially conformally deposited in the second trenches 314 and fills into the notch in the first conductive layers 113, and the second metal layer 318 fills the remaining part of the second trenches 314. In some embodiments, after the first metal layer 316 and the second metal layer 318 are deposited sequentially in the second trenches 314, the first metal layer 316 and the second metal layer 318 are planarized to form the first bonding pads 117 including the first metal layers 118 and the second metal layers 119. In some embodiments, the first metal layer 316 and the second metal layer 318 are deposited by the deposition process such as PVD, sputtering, plating, another deposition process, or any suitable combination thereof. In some embodiments, the first metal layer 316 and the second metal layer 318 are planarized by CMP. In some embodiments, the first metal layer 316 and the second metal layer 318 are planarized until the top surfaces of the first metal layer 316 and the second metal layer 318 is aligned with the top surface of the inorganic barrier layer 115. In some embodiments, the first metal layer 316 and the second metal layer 318 include the same materials. In some embodiments, the first metal layer 316 and the second metal layer 318 include different materials. In some embodiments, the first metal layer 316 and the second metal layer 318 respectively include TaN, Ta, TiN, Ti, Cu, or combinations thereof. In some embodiments, a grain size of the first metal layer 316 is greater than a grain size of the second metal layer 318. In some embodiments, the grain size of the first metal layer 316 is greater than 100 nanometers (nm). In some embodiments, the grain size of the first metal layer 316 is between 100 nm and 5000 nm, such as 100, 200, 400, 600, 800, 1000, 1200, 1400, 1600, 1800, 2000, 2200, 2400, 2600, 2800, 3000, 3200, 3400, 3600, 3800, 4000, 4200, 4400, 4600, 4800, or 5000 nm. In some embodiments, the grain size of the second metal layer 318 is less than 100 nm, such as 10, 15, 20, 25, 30, 35, 40, 45, 50, 55, 60, 65, 70, 75, 80, 85, 90, 95, or 100 nm. The grain size of the first metal layer 316 greater than the grain size of the second metal layer 318 (less than 100 nm) boosts the forming speed of the first bonding pads 117, compared to the bonding pads merely include the grain size of the metal layer less than 100 nm. The first bonding pads 117 formed in the second trenches 314 and contact with the first conductive layers 113 may increase the contact area between the first conductive layers 113 and the first bonding pads 117, such that the resistance of the first conductive layers 113 and the first bonding pads 117 become smaller, compared to the semiconductor structure that the bonding pads depositing in the trenches does not extend into the conductive layers.

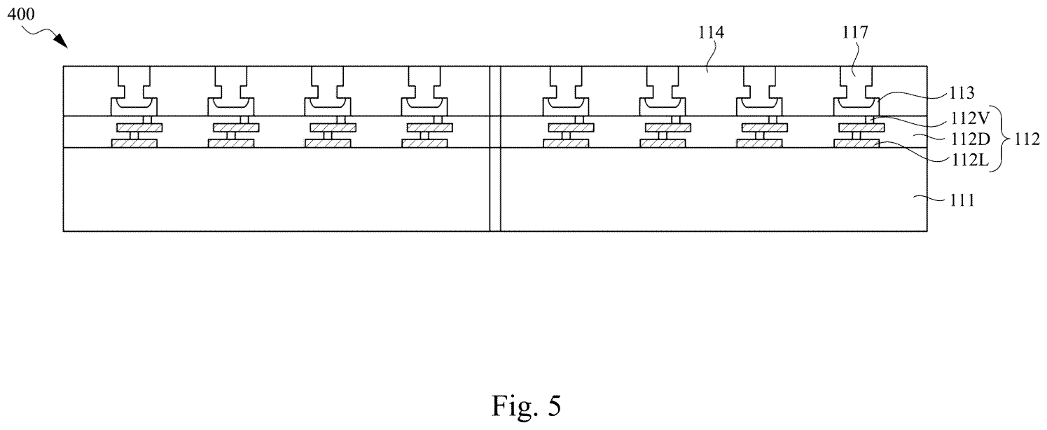

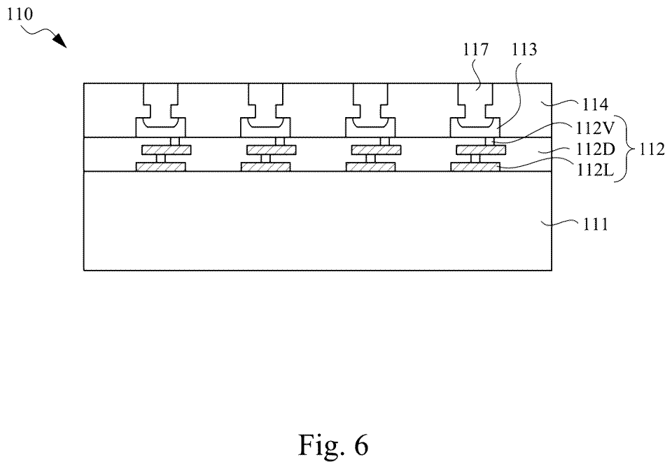

FIG. 5 is a cross-section view of the semiconductor structure 400 after finishing the operations 202-214. The first chip 110 is formed after the singulation process of the semiconductor structure 400, as shown in FIG. 6.

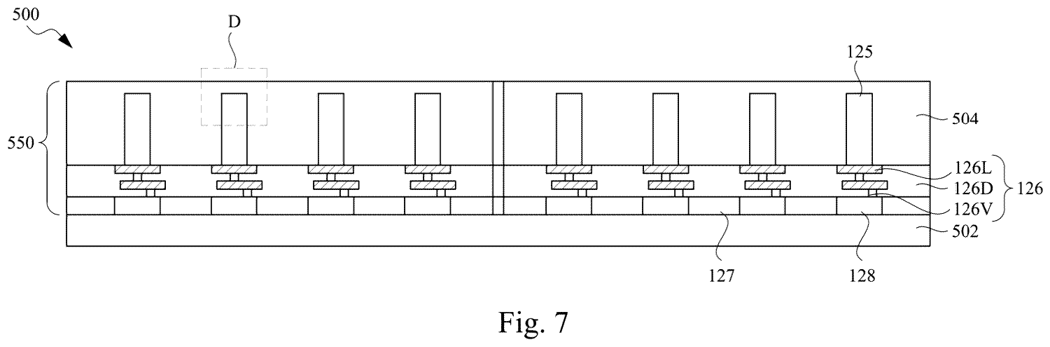

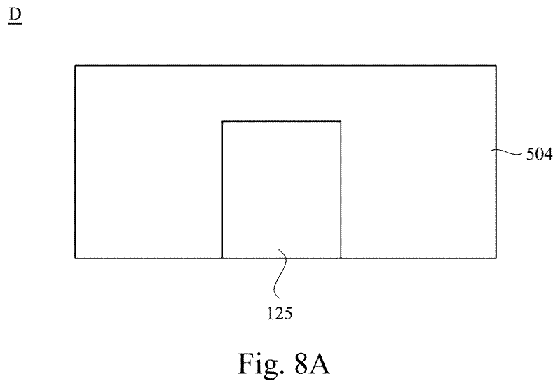

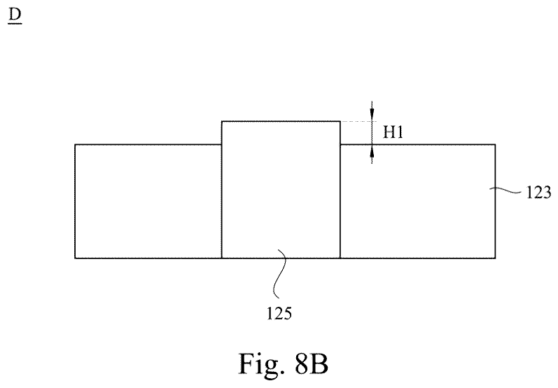

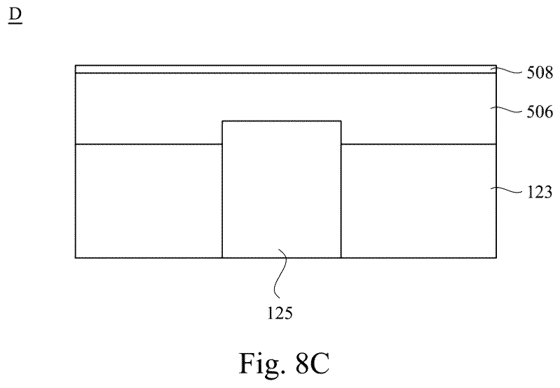

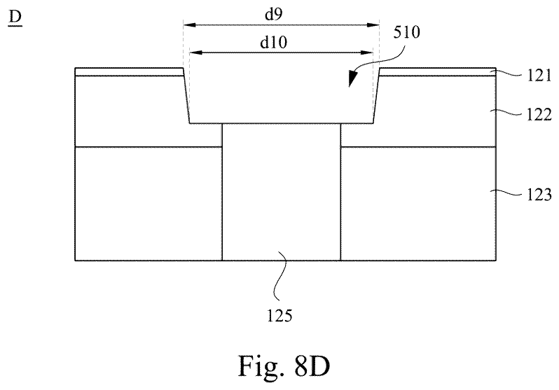

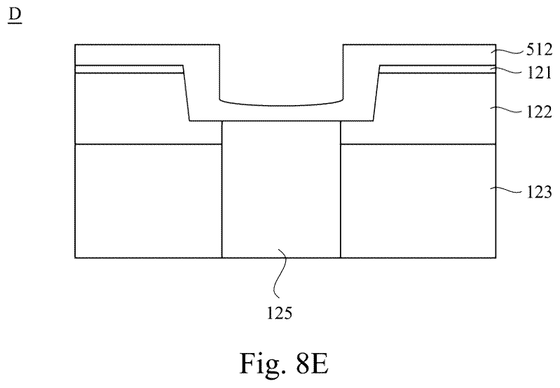

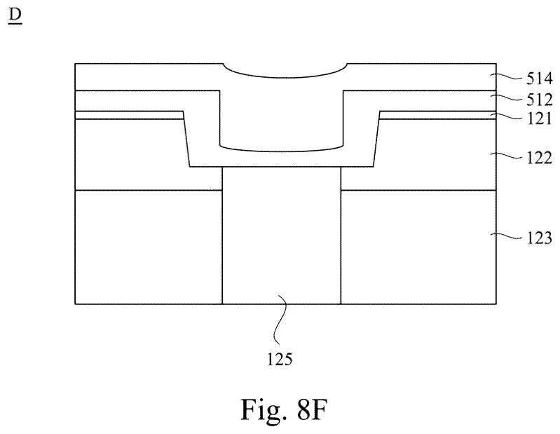

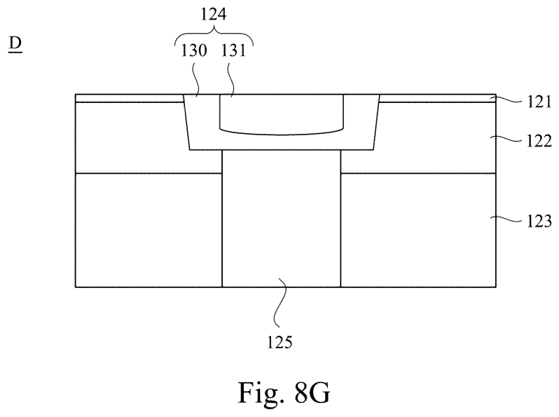

FIG. 7 is a cross-section view of the semiconductor structure 500. In some embodiments, the semiconductor structure 550 is bonded to the carrier 502 through an adhesive layer (not shown) to form the semiconductor structure 500, as shown in FIG. 7. In some embodiments, the carrier 502 includes Si, ceramics, metal, or the like. In some embodiments, the adhesive layer includes strippable materials or materials that easy to remove, such as epoxy resin, or other suitable adhesive materials. FIG. 8A is an enlarged diagram of the section D in FIG. 7. Referring to FIGS. 2B, 7, and 8A, in operation 216, the third dielectric layer 127, one or more second conductive layers 128, the second interconnect layer 126, a first substrate 504, and one or more through silicon vias 125 are received to form a semiconductor structure 550. In detail, the second conductive layers 128 are embedded in the third dielectric layer 127. The second interconnect layer 126 is formed on the third dielectric layer 127 and the second conductive layers 128. The first substrate 504 is formed on the second interconnect layer 126. The through silicon vias 125 are embedded in the first substrate 504.

As shown in FIGS. 2B, 8A, and 8B, in operation 218, the first substrate 504 is etched and grinded to expose one or more through silicon vias 125 and to form the first substrate 123. In some embodiments, the first substrate 504 is etched by the dry etching process. In some embodiments, a protrusion height H1 of the through silicon vias 125 is between 3 micrometer (μm) and 8 μm, such as 3, 4, 5, 6, 7, or 8 μm.

Refer to FIGS. 2B, 8B, and 8C, in operation 220, a second dielectric layer 506 is formed to cover the first substrate 123 and the through silicon vias 125. In some embodiments, after the second dielectric layer 506 is formed to cover the first substrate 123 and the through silicon vias 125, an inorganic barrier layer 508 is formed on the second dielectric layer 506. In some embodiments, the second dielectric layer 506 and the inorganic barrier layer 508 is formed by the deposition process, for example and without limitation, CVD, PVD, ALD, LPCVD, another deposition process, or any suitable combination thereof.

Referring to FIGS. 2B, 8C and 8D, in operation 222, the second dielectric layer 506 is etched to form one or more third trenches 510 and the second dielectric layer 122, and to expose the through silicon vias 125. In some embodiments, before the second dielectric layer 506 is etched, the inorganic barrier layer 508 is etched to form the inorganic barrier layer 121. In some embodiments, the second dielectric layer 506 and the inorganic barrier layer 508 are etched by the dry etching process. In some embodiments, a cross-sectional view of the third trenches 510 includes a top width d9 and a bottom width d10. In some embodiments, the top width d9 is greater or same as the bottom width d10. In some embodiments, the cross-sectional view of the third trenches 510 is a trapezoid or rectangle, but the present disclosure is limited thereto.

Referring to FIGS. 2B, and 8D-8G, in operation 224, one or more second bonding pads 124 are formed in the third trenches 510. In some embodiments, the second bonding pads 124 formed in the third trenches 510 include the first metal layer 512 and the second metal layer 514 formed sequentially in the third trenches 510. In detail, the first metal layer 512 is conformally deposited in the third trenches 510 and the second metal layer 514 fills in the remaining part of the third trenches 510. In some embodiments, after the first metal layer 512 and the second metal layer 514 is formed sequentially in the third trenches 510, the first metal layer 512 and the second metal layer 514 are planarized to form the second bonding pads 124 including the first metal layer 130 and the second metal layer 131. In some embodiments, the first metal layer 512 and the second metal layer 514 are formed by the deposition process such as PVD, sputtering, plating, another deposition process, or any suitable combination thereof. In some embodiments, the first metal layer 512 and the second metal layer 514 are planarized by CMP. In some embodiments, the first metal layer 512 and the second metal layer 514 are planarized until the top surfaces of the first metal layer 512 and the second metal layer 514 is aligned with the top surface of the inorganic barrier layer 121. In some embodiments, the first metal layer 512 and the second metal layer 514 include the same materials. In some embodiments, the first metal layer 512 and the second metal layer 514 include different materials. In some embodiments, the first metal layer 512 and the second metal layer 514 respectively include TaN, Ta, TiN, Ti, Cu, or combinations thereof. In some embodiments, a grain size of the first metal layer 512 is greater than a grain size of the second metal layer 514. In some embodiments, the grain size of the first metal layer 512 is greater than 100 nm. In some embodiments, the grain size of the first metal layer 512 is between 100 nm and 5000 nm, such as 100, 200, 400, 600, 800, 1000, 1200, 1400, 1600, 1800, 2000, 2200, 2400, 2600, 2800, 3000, 3200, 3400, 3600, 3800, 4000, 4200, 4400, 4600, 4800, or 5000 nm. In some embodiments, the grain size of the second metal layer 514 is less than 100 nm, such as 10, 15, 20, 25, 30, 35, 40, 45, 50, 55, 60, 65, 70, 75, 80, 85, 90, 95, or 100 nm. The grain size of the first metal layer 512 greater than the grain size of the second metal layer 514 (less than 100 nm) boosts the forming speed of the second bonding pads 124, compared to the bonding pads merely include the grain size of the metal layer less than 100 nm.

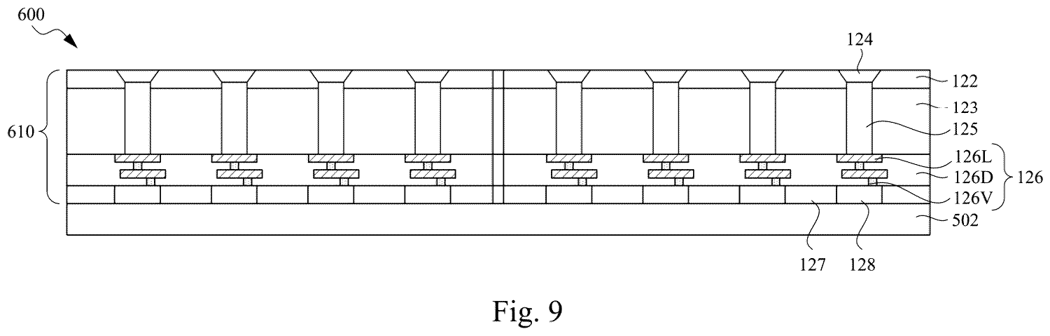

As shown in FIG. 9, after finishing the operations 216-224, a semiconductor structure 600 is formed. The semiconductor structure 600 includes a semiconductor structure 610 and the carrier 502. The semiconductor structure 610 includes the inorganic barrier layer 121, the second dielectric layer 122, the first substrate 123, the second bonding pad 124, the through silicon via 125, the second interconnect layer 126, the third dielectric layer 127, and the second conductive layer 128.

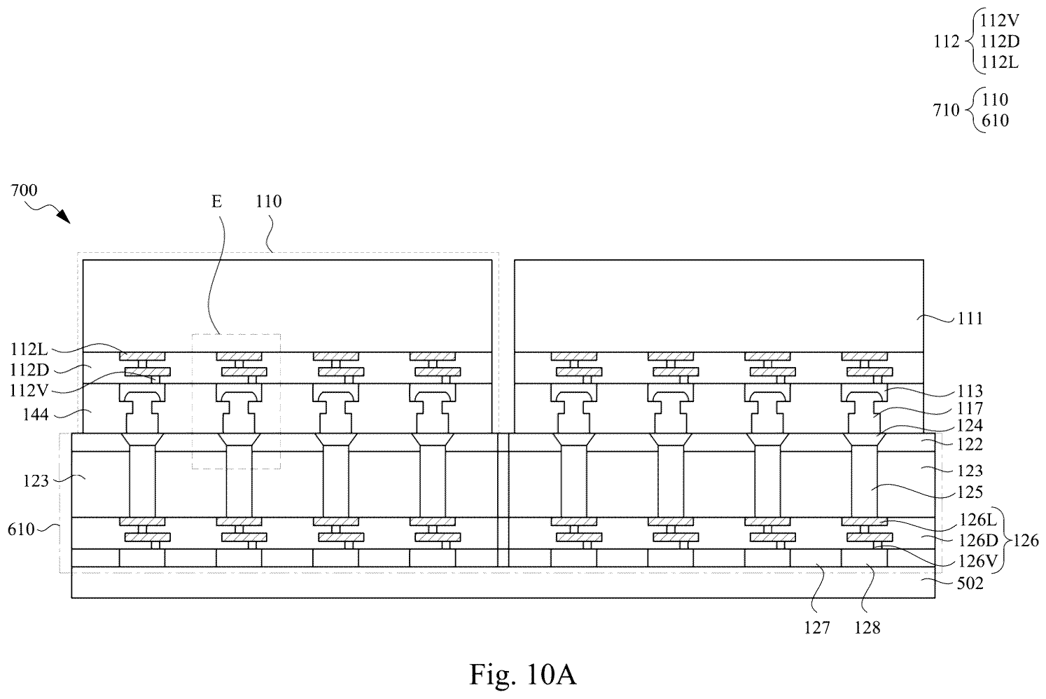

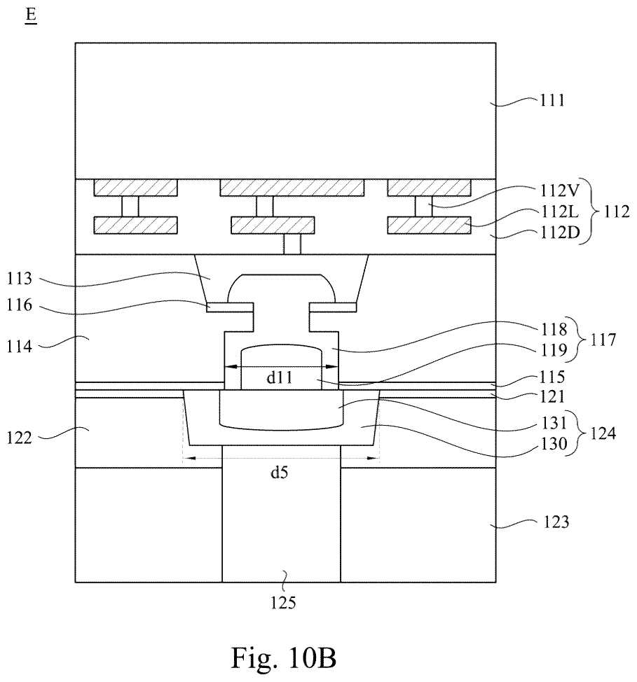

FIG. 10A is a cross-sectional view of a semiconductor structure 700. FIG. 10B is an enlarged diagram of the section E in FIG. 10A. To simplify the diagram in FIG. 10A, portions of the semiconductor components are merely shown in FIG. 10B, but not shown in FIG. 10A. Referring to FIGS. 2B, 10A, and 10B, in operation 226, the first bonding pads 117 are bonded to the second bonding pads 124. Also, the first chips 110 are inverted and stacked on the semiconductor structure 610 to form a semiconductor structure 700. The semiconductor structure 700 includes a semiconductor structure 710 and the carrier 502. The semiconductor structure 710 includes the first chips 110 and the semiconductor structure 610. A bonded temperature of the first bonding pads 117 bonded to the second bonding pads 124 is between 150° C. and 250° C., such as 150, 160, 170, 180, 190, 200, 210, 220, 230, 240, or 250° C. According to the aforementioned illustrations, the first bonding pads 117 and the second bonding pads 124 include the second metal layers 119 and the second metal layers 131, respectively. Due to the small grain size (less than 100 nm) of the second metal layers 119 and 131, the bonded temperature of the first bonding pads 117 bonded to the second bonding pads 124 decrease. Besides, when the first bonding pads 117 and the second bonding pads 124 are bonded, the second metal layers 119 of the first bonding pads 117 and the second metal layers 131 of the second bonding pads 124 are fused. Additionally, the bottom width d5 of the second bonding pads 124 is greater than a width d11 of the bottom of the first bonding pads 117, which causes no requirements for accurate alignment between the first bonding pads 117 and the second bonding pads 124.

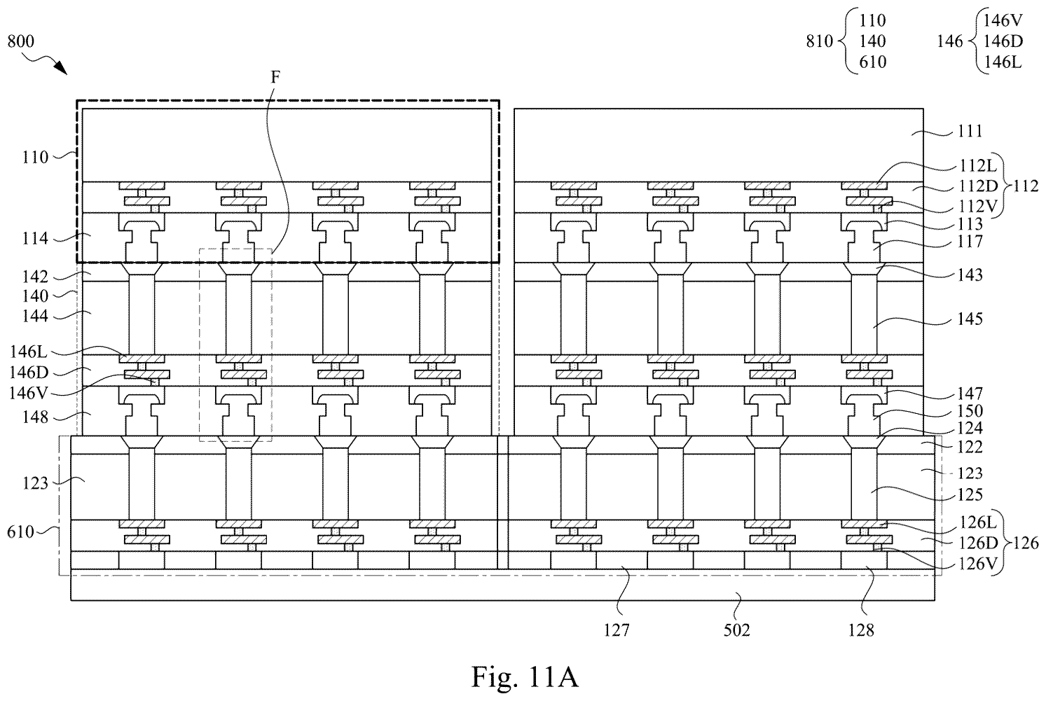

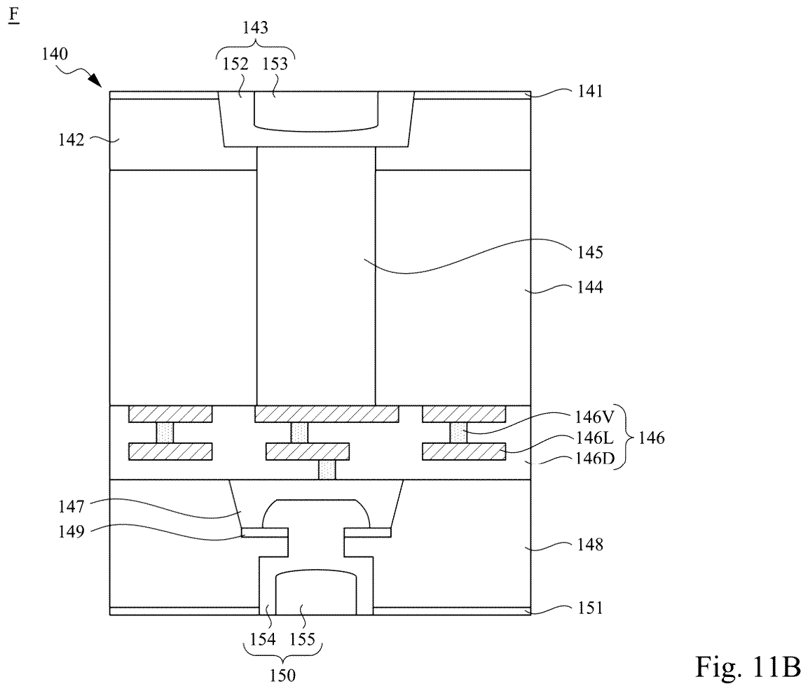

FIG. 11A is a cross-sectional view of a semiconductor structure 800. FIG. 11B is an enlarged diagram of the section F in FIG. 11A. To simplify the diagram in FIG. 11A, portions of the semiconductor components are merely shown in FIG. 11B, but not shown in FIG. 11A. In another embodiment, the first chips 140 are stacked on the semiconductor structure 610 and the first chips 110 are stacked on the first chips 140 to form the semiconductor structure 800. The semiconductor structure 800 includes a semiconductor structure 810 and the carrier 502. The semiconductor structure 810 includes the first chips 110, the first chips 140, and the semiconductor structure 610. That is, in operation 226, the first bonding pads 150 and 117 are bonded to the second bonding pads 124 and 143, respectively. The formation of the first chip 140 includes the following processes. Refer to the aforementioned operations 202-214 for the formation of the substrate 111, the first interconnect layer 146, the first conductive layer 147, the first dielectric layer 148, the anti-reflection layer 149, the first bonding pad 150, and the inorganic barrier layer 151, in which after performing operation 202, the substrate 111 is etched to form one or more trenches (not shown) and followed by the formation of the through silicon vias 145 in the trenches. Then, after performing operation 214, the formed semiconductor structure is inverted to facilitate the subsequent operations. Subsequently, refer to the aforementioned operations 218-224 for the formation of the inorganic barrier layer 141, the second dielectric layer 142, the second bonding pads 143, and the substrate 144. Please refer to the aforementioned embodiments of the inorganic barrier layer 121, the second dielectric layer 122, the second bonding pads 124, the first substrate 123, the through silicon vias 125, the second interconnect layer 126, the first conductive layer 113, the first dielectric layer 114, the anti-reflection layer 116, the first bonding pad 117, the inorganic barrier layer 115 for the embodiments of the inorganic barrier layer 141, the second dielectric layer 142, the second bonding pads 143, and the substrate 144, the through silicon vias 145, the first interconnect layer 146, the first conductive layer 147, the first dielectric layer 148, the anti-reflection layer 149, the first bonding pad 150, and the inorganic barrier layer 151. Please refer to the aforementioned embodiments of the semiconductor structure 700 for the embodiments of semiconductor structure 800. It is noted that any numbers of the first chips 140 may stacked between the semiconductor structure 610 and the first chips 110, e.g., two, three, four, five, etc. Besides, the semiconductor structure 800 includes all the advantages which described in the aforementioned semiconductor structure 700.

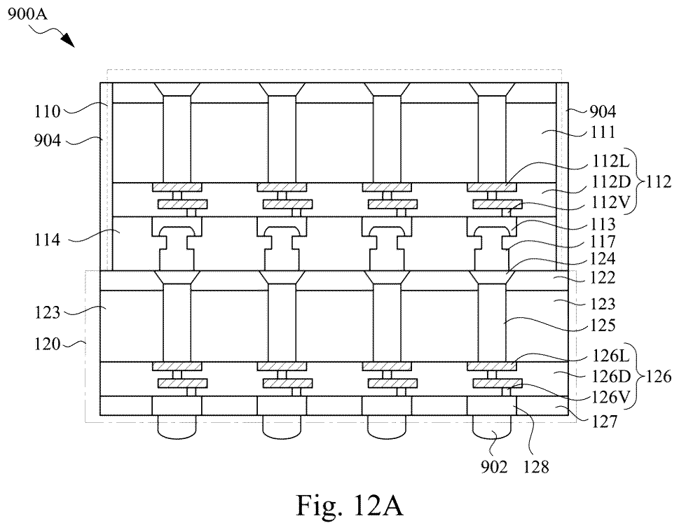

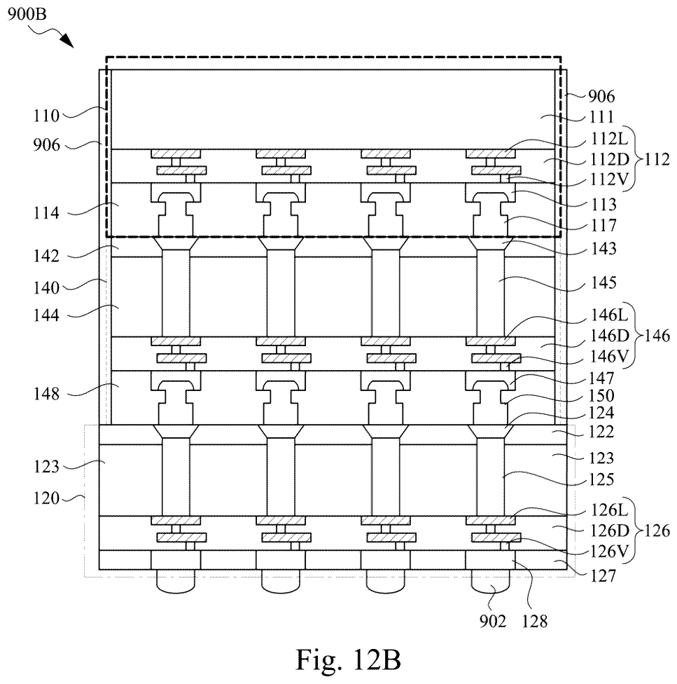

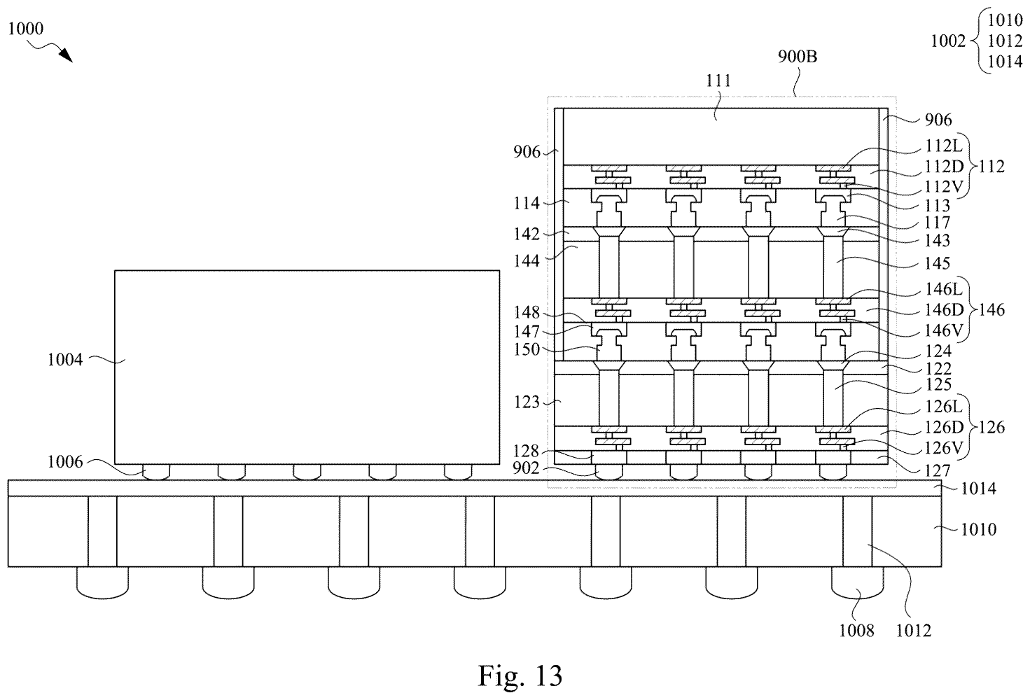

FIGS. 12A-13 are cross-sectional views illustrating intermediate stages of manufacturing a semiconductor package structure 1000 according to various embodiments of the present disclosure. Referring to FIGS. 10A, 11A, 12A, and, 12B, after finishing the operations 202-226, the outer side of the first chips 110/140 and the top side of the second chip 120 are surrounded with a molding material 904 and 906. In some embodiments, the molding materials 904 and 906 include polymer, epoxy, resin, or other suitable materials. Afterwards, the semiconductor structures 710 and 810 and the carrier 502 are debonded and followed by the installation of one or more conductive members 902 at the bottom of the second conductive layer 128 in the second chip 120. Subsequently, the dicing process of the semiconductor structures 710 and 810 is performed to form the semiconductor structures 900A and 900B. In some embodiments, the conductive members 902 include metal materials, such as tin (Sn), Cu, nickel (Ni), gold (Au), or other suitable metal materials.

FIG. 13 is one embodiment of the semiconductor package structure 1000. Referring to FIG. 13, after the semiconductor structure 900B is formed, the semiconductor structure 900B is disposed on and connected to an interposer 1002, and a logic die 1004 is disposed on and connected to the interposer 1002 by one or more conductive members 1006 at the bottom of the logic die 1004, similarly. Afterwards, the interposer 1002 is disposed on and connected to a substrate (not shown) through a through silicon vias 1012 in the interposer 1002 and one or more conductive members 1008 at the bottom of the interposer 1002 to form the semiconductor package structure 1000. In some embodiments, the semiconductor structure 900B in the semiconductor package structure 1000 may be replaced by the semiconductor structure 900A or other semiconductor structures. In some embodiments, the semiconductor structure 900A/900B is high bandwidth memory (HBM). In some embodiments, the logic die 1004 include, for example and without limitation, application specific integrated circuit (ASIC), central processing unit (CPU), graphics processing unit (GPU). In some embodiments, the interposer 1002 includes a substrate 1010, the through silicon vias 1012 embedded in the substrate 1010, an interconnect layer 1014 disposed on the through silicon vias 1012 and the substrate 1010, the conductive members 1008 disposed below the through silicon vias 1012. Please refer to the aforementioned embodiments of the conductive members 902, substrate (the substrate 111/the first substrate 123/the substrate 144), and interconnect layer (the first interconnect layer 112/the second interconnect layer 126/the first interconnect layer 146) for the embodiments of the conductive members 1008, the substrate 1010, and the interconnect layer 1014.

In summary, the present disclosure provides a semiconductor structure and a method of manufacturing the semiconductor structure. In the semiconductor structure, the bonding pad extends into the conductive layer, causing the increase of the contact area therebetween and the reduction of the resistance of the conductive layer and the bonding pad. In some embodiments, the grain size of the first metal layer greater than the grain size of the second metal layer (less than 100 nm) boosts the forming speed of the bonding pad, compared to the bonding pad merely includes the grain size of the metal layer less than 100 nm. Besides, the grain size of the second metal layers of the first bonding pad and the second bonding pad are less than 100 nm, which decreases the bonded temperature of the first bonding pad bonded to the second bonding pad.

Although the present disclosure has been described in considerable detail with reference to certain embodiments, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover the modifications and variations of the present disclosure falling within the scope of the appended claims.

What is claimed is:

1. A semiconductor structure, comprising:
a first chip comprising:
a first interconnect layer;
a first conductive layer disposed on the first interconnect layer;
a first dielectric layer covering the first conductive layer; and
a first bonding pad embedded in the first dielectric layer and extending into the first conductive layer.

2. The semiconductor structure of claim 1, wherein the first chip further comprises an anti-reflection layer disposed between the first conductive layer and the first dielectric layer and on the first conductive layer.

3. The semiconductor structure of claim 1, wherein the first bonding pad comprises a first metal layer and a second metal layer, and the first metal layer surrounds the second metal layer.

4. The semiconductor structure of claim 1, wherein a cross-section of the first bonding pad comprises:
a top width;
a bottom width; and
a middle width that is less than or the same as the top width and the bottom width.

5. The semiconductor structure of claim 4, wherein the top width is greater than the bottom width.

6. The semiconductor structure of claim 1, further comprising:
a second chip disposed on the first chip, wherein the second chip comprises:
a second dielectric layer;
a substrate disposed on the second dielectric layer;
a second bonding pad embedded in the second dielectric layer and bonded to the first bonding pad; and
a through silicon via embedded in the second dielectric layer and the substrate and in contact with the second bonding pad.

7. The semiconductor structure of claim 6, wherein a bonding interface between the first bonding pad and the second bonding pad is substantially flat.

8. The semiconductor structure of claim 6, wherein the second bonding pad comprises a first metal layer and a second metal layer, and the first metal layer surrounds the second metal layer.

9. The semiconductor structure of claim 6, wherein a cross-section of the second bonding pad comprises:
a top width; and
a bottom width that is greater or the same as the top width.

10. A method of manufacturing a semiconductor structure, comprising:
forming a first conductive layer on a first interconnect layer;
forming a first dielectric layer on the first conductive layer and the first interconnect layer;
etching the first dielectric layer to form a first trench on the first conductive layer;
etching a portion of the first conductive layer to form a second trench; and
forming a first bonding pad in the second trench.

11. The method of manufacturing the semiconductor structure of claim 10, further comprising:
before forming the first dielectric layer on the first conductive layer and the first interconnect layer, forming an anti-reflection layer on the first conductive layer; and
before etching the portion of the first conductive layer to form the second trench, etching a portion of the anti-reflection layer.

12. The method of manufacturing the semiconductor structure of claim 10, wherein forming the first bonding pad in the second trench comprises sequentially depositing a first metal layer and a second metal layer in the second trench.

13. The method of manufacturing the semiconductor structure of claim 12, wherein a grain size of the first metal layer is greater than a grain size of the second metal layer.

14. The method of manufacturing the semiconductor structure of claim 10, further comprising:
receiving a first substrate and a through silicon via embedded in the first substrate;
etching the first substrate to expose the through silicon via;
forming a second dielectric layer to cover the first substrate and the through silicon via;
etching the second dielectric layer to form a third trench and to expose the through silicon via;
forming a second bonding pad in the third trench; and
bonding the first bonding pad to the second bonding pad.

15. The method of manufacturing the semiconductor structure of claim 14, wherein forming the second bonding pad in the third trench comprises sequentially forming a first metal layer and a second metal layer in the third trench.

16. The method of manufacturing the semiconductor structure of claim 15, wherein a grain size of the first metal layer is greater than a grain size of the second metal layer.
